(19) United States
(12) Patent Application Publication
(10) Pub. No.: US 2019/0051776 A1
(43) Pub. Date: Feb. 14, 2019

(54) BI-FACIAL TRANSPARENT SOLAR CELL

(71) Applicant: ELECTRONICS AND TELECOMMUNICATIONS RESEARCH INSTITUTE, Daejeon (KR)

(72) Inventors: JungWook LIM, Daejeon (KR); Ga Young KIM, Daejeon (KR)

(73) Assignee: ELECTRONICS AND TELECOMMUNICATIONS RESEARCH INSTITUTE, Daejeon (KR)

(21) Appl. No.: 16/057,082

(22) Filed: Aug. 7, 2018

(30) Foreign Application Priority Data
Aug. 9, 2017 (KR) 10-2017-0101294
Dec. 8, 2017 (KR) 10-2017-0168236

(51) Int. Cl. H01L 31/0224; H01L 31/054; H01L 31/075; H01L 31/048; H01L 31/18

(52) U.S. Cl. CPC H01L 31/022466; H01L 31/054; H01L 31/1804; H01L 31/0488; H01L 31/075

(57) ABSTRACT

Provided is a bi-facial transparent solar cell including a first substrate and a second substrate disposed on the first substrate, a light absorbing layer disposed between the first substrate and the second substrate, a first transparent electrode disposed between the first substrate and the light absorbing layer, and a second transparent electrode disposed between the second substrate and the light absorbing layer. The first transparent electrode and the second transparent electrode may each transmit light having wavelengths different from each other.

### CROSS-REFERENCE TO RELATED APPLICATIONS

This U.S. non-provisional patent application claims priority under 35 U.S.C. § 119 to Korean Patent Application Nos. 10-2017-0101294, filed on Aug. 9, 2017, and 10-2017-0168236, filed on Dec. 8, 2017, in the Korean Intellectual Property Office, the entire contents of which are hereby incorporated by reference.

### TECHNICAL FIELD

The present disclosure herein relates to a bi-facial transparent solar cell, and more particularly, to a bi-facial transparent solar cell capable of performing indoor-light power generation.

### DISCUSSION OF THE RELATED ART

A solar cell is a photovoltaic energy conversion system that converts light energy emitted from the sun into electrical energy. Crystalline silicon solar cells occupy most of a solar cell market. The crystalline silicon solar cells may be difficult to be realized in solar cells with various shapes and materials, may be also difficult to be realized in transparent solar cells, and may not perform indoor-light power generation. However, a thin-film silicon solar cell may be realized in various shapes and materials, realized in transparent solar cell, and perform the indoor-light power generation. Also, a silicon material of the thin-film silicon solar cell has advantages such as nonpoisonous, plentiful, and stable.

The solar cell is unnecessary to have a transparent structure when the solar cell is manufactured as a general panel that is installed at a sunlight power generation system or on a roof of a building. However, the crystalline silicon solar cells having the above-described structure may not be used at a window or an outer glass wall of a building, which necessarily transmits external sunlight, and may decrease in aesthetic property when used as a partial open type. In recent years, the solar cell is used for a window or a glass for a vehicle to serve as an auxiliary power supply source.

### SUMMARY

The present disclosure provides a bi-facial transparent solar cell having improved light absorbance efficiency, and more particularly, to a solar cell capable of performing indoor-light power generation while having transparency.

The object of the present invention is not limited to the aforesaid, but other objects not described herein will be clearly understood by those skilled in the art from descriptions below.

According to exemplary embodiments of the inventive concepts provides a bi-facial transparent solar cell including: a first substrate and a second substrate disposed on the first substrate; a light absorbing layer disposed between the first substrate and the second substrate; a first transparent electrode disposed between the first substrate and the light absorbing layer; and a second transparent electrode disposed between the second substrate and the light absorbing layer. The first transparent electrode and the second transparent electrode each transmit lights having wavelengths different from each other. Through this, light may be absorbed and transmitted through all of both sides to perform bi-facial power generation. In particular, the power generation may be performed even when indoor light is supplied to all of the both sides in addition to when either sunlight or indoor light is supplied.

In an embodiment, the first transparent electrode may include a first light transmittance control layer and a first selective wavelength control layer, which are sequentially stacked toward the first substrate from the light absorbing layer. The second transparent electrode may include a second light transmittance control layer and a second selective wavelength control layer, which are sequentially stacked toward the second substrate from the light absorbing layer.

In an embodiment, the bi-facial transparent solar cell may further include a conductive layer disposed on at least one of both surfaces of the first light transmittance control layer and at least one of both surfaces of the second light transmittance control layer.

In an embodiment, the bi-facial transparent solar cell may further include: a first seed layer disposed between the first substrate and the first selective wavelength control layer; and a second seed layer disposed between the second light transmittance control layer and the light absorbing layer.

In an embodiment, the first light transmittance control layer or the second light transmittance control layer may be provided in plurality.

In an embodiment, the first light transmittance control layer and the second light transmittance control layer may have thicknesses different from each other. The first selective wavelength control layer and the second selective wavelength control layer may have thicknesses different from each other.

Each of the transmittance control layer and the selective wavelength control layer may have a structure and a thickness, which are controlled to be designed in optimized value according to a spectrum of indoor light. The solar cell may have maximized efficiency and transparency through effective control in bi-facial power generation, in which sunlight and indoor light are illuminated to both sides.

In an embodiment, the light absorbing layer may include a P-layer, an I-layer, and an N-layer, which are sequentially stacked.

In an embodiment, the bi-facial transparent solar cell may further include a reaction enhancing layer disposed at least one of between the P-layer and the I-layer and between the I-layer and the N-layer.

In an embodiment, the light absorbing layer may contain amorphous silicon, microcrystalline silicon, silicon-germanium, a silicon oxide, a silicon nitride, or a silicon carbide.

In an embodiment, light incident into the first transparent electrode may be sunlight. Light incident into the second transparent electrode may be indoor light.

In an embodiment, the indoor light may be light emitted from a bulb color LED, a daylight LED, or a fluorescent lamp.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a cross-sectional view for explaining a bi-facial transparent solar cell according to embodiments of the inventive concept;

FIG. 2 is a schematic view for explaining an operation of the bi-facial transparent solar cell according to embodiments of the inventive concept;

FIG. 3 is a schematic view for explaining a window to which the bi-facial transparent solar cell according to embodiments of the inventive concept is applied;

FIG. 4 is a cross-sectional view for explaining an operation of a first transparent electrode;

FIG. 5 is a cross-sectional view for explaining a transmittance of the first transparent electrode;

FIG. 6 is a graph exemplarily illustrating a wavelength of light incident into the first transparent electrode;

FIG. 7 is a graph for explaining a power production efficiency of the bi-facial transparent solar cell according to embodiments of the inventive concept; and

FIG. 8 is a cross-sectional view for explaining the bi-facial transparent solar cell according to embodiments of the inventive concept.

### DETAILED DESCRIPTION

Exemplary embodiments of the present invention will be described with reference to the accompanying drawings so as to sufficiently understand constitutions and effects of the present invention. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. A person with ordinary skill in the technical field of the present invention pertains will be understood that the present invention can be carried out under any appropriate environments.

In the following description, the technical terms are used only for explaining a specific exemplary embodiment while not limiting the inventive concept. In this specification, the terms of a singular form may include plural forms unless specifically mentioned. The meaning of ‘comprises’ and/or ‘comprising’ specifies a component, a step, an operation and/or an element does not exclude other components, steps, operations and/or elements.

In the specification, it will be understood that when a layer (or film) is referred to as being ‘on’ another layer or substrate, it can be directly on the other layer or substrate, or intervening layers may also be present.

Also, though terms like a first, a second, and a third are used to describe various regions and layers (or films) in various embodiments of the present invention, the regions and the layers are not limited to these terms. These terms are used only to discriminate one region or layer (or film) from another region or layer (or film). Therefore, a layer referred to as a first layer in one embodiment can be referred to as a second layer in another embodiment. An embodiment described and exemplified herein includes a complementary embodiment thereof. Like reference numerals refer to like elements throughout.

Unless terms used in embodiments of the present invention are differently defined, the terms may be construed as meanings that are commonly known to a person skilled in the art.

Hereinafter, a bi-facial transparent solar cell according to an embodiment of the inventive concept will be described with reference to the accompanying drawings. The bi-facial transparent solar cell may be a bi-facial transmission type solar cell.

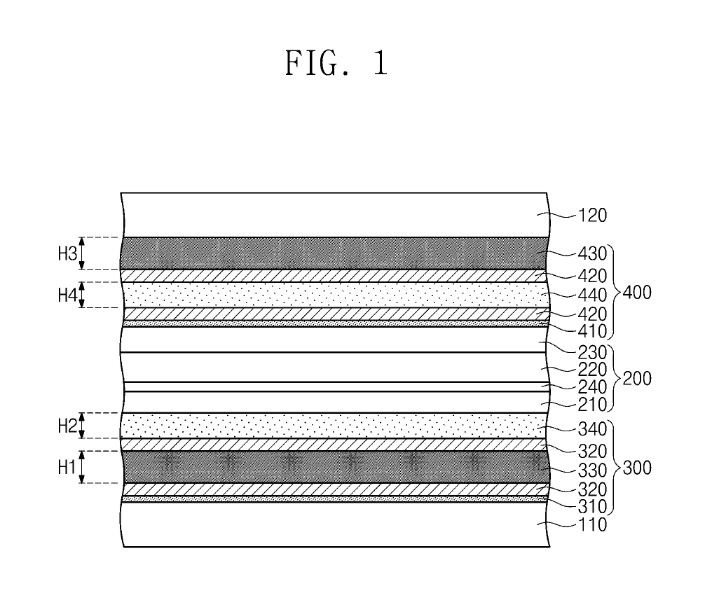

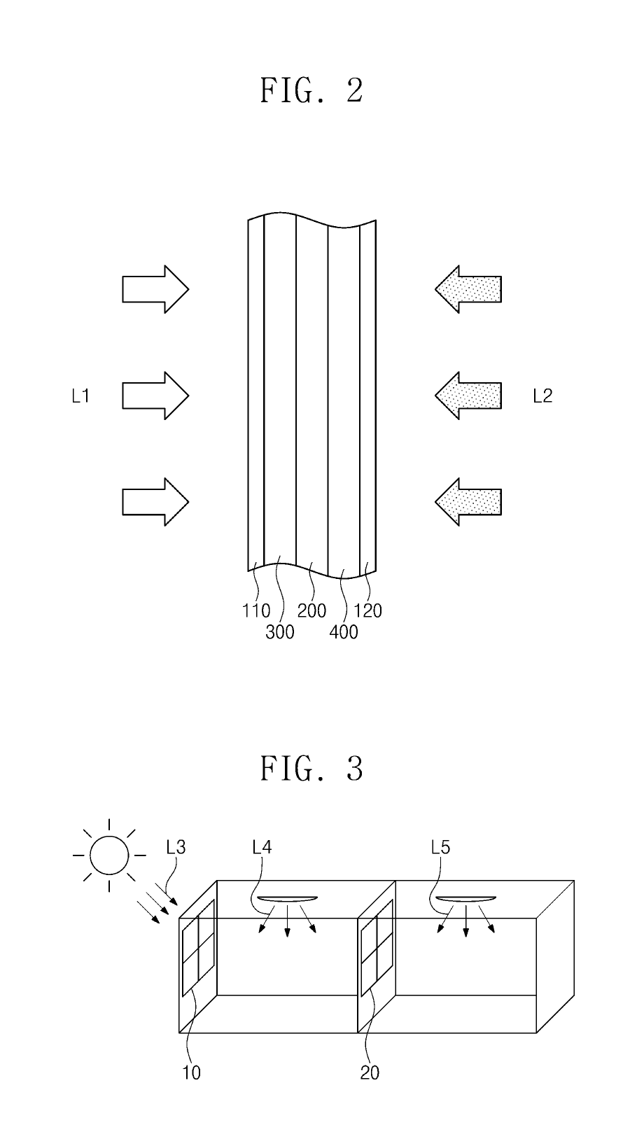

FIG. 1 is a cross-sectional view for explaining a bi-facial transparent solar cell according to embodiments of the inventive concept. FIG. 2 is a schematic view for explaining an operation of the bi-facial transparent solar cell according to embodiments of the inventive concept.

Referring to FIGS. 1 and 2, the bi-facial transparent solar cell includes a light absorbing layer 200. A first transparent electrode 300 may be disposed on one surface of the light absorbing layer 200, and then a first substrate 110 may be disposed on the first transparent electrode 300 in order. A second transparent electrode 400 may be disposed on the other surface of the light absorbing layer 200, and then a second substrate 120 may be disposed on the second transparent electrode 400 in order.

The second substrate 120 may be disposed on the first substrate 110. The first substrate 110 and the second substrate 120 may be transparent glass substrates. Each of the first substrate 110 and the second substrate 120 may have a refractive index of about 1.5. First light L1 may be incident into the first substrate 110, and second light L2 may be incident into the second substrate 120. The first light L1 and the second light L2 may have wavelengths different from each other. For example, the first light L1 may be sunlight, and the second light L2 may be indoor illumination light. Alternatively, the first light L1 and the second light L2 may be indoor light having optical spectra different from each other.

The light absorbing layer 200 may be disposed between the first substrate 110 and the second substrate 120. The light absorbing layer 200 may be a single layer and/or multi-layers. The light absorbing layer 200 may be a silicon layer. In particular, the light absorbing layer 200 may be an amorphous silicon layer (a-Si:H) or a microcrystalline silicon layer (μc-Si:H). The light absorbing layer 200 may include silicon-germanium, a silicon oxide, a silicon nitride, or a silicon carbide. The light absorbing layer 200 may have a stacked structure in which a P-layer 210, an I-layer 220, and an N-layer 230 are sequentially stacked. The P-layer 210 included in the light absorbing layer 200 may be disposed adjacent to the first substrate 110. Unlike the P-layer, the N-layer 230 included in the light absorbing layer 200 may be disposed adjacent to the second substrate 120. The P-layer 210 may be a silicon layer containing a p-type dopant, the I-layer 220 may be an intrinsic semiconductor layer in which impurities are not doped, and the N-layer 230 may be a silicon layer containing a n-type dopant. For example, the P-layer 210 may be a layer doped by group 3 elements such as boron (B), gallium (Ga), and indium (In). For example, the N-layer 230 may be a layer doped by group 5 elements such as phosphorus (P), arsenic (As), and antimony (Sb). The light absorbing layer 200 may have a thickness of about 500 Å to about 2000 Å. When the light absorbing layer 200 has a thickness greater than about 2000 Å, since light hardly transmits the bi-facial transparent solar cell, the transparent solar cell may not be realized. Also, when the light absorbing layer 200 has a thickness less than about 500 Å, a function of the light absorbing layer 200 may not be realized. The N-layer 230 may have a thickness greater than that of the P-layer 210, and the I-layer 220 may have a thickness greater than that of each of the P-layer 210 and the N-layer 230. In particular, when the light absorbing layer 200 has a thickness of about 2000 Å, the P-layer 210 may have a thickness of about 100 Å to about 180 Å, the I-layer 220 may have a thickness of about 1500 Å, and the N-layer 230 may have a thickness of about 250 Å to 350 Å.

According to another embodiment, the I-layer 220 may not be provided. That is, the light absorbing layer 200 may include the P-layer 210 and the N-layer 230, which contact each other, and the p-n junction may be formed between the P-layer 210 and the N-layer 230. The p-n junction may form an electric field. Hereinafter, the light absorbing layer 200 including all of the P-layer 210, the I-layer 220, and N-layer 230 will be described as a reference.

A reaction enhancing layer 240 may be disposed in the light absorbing layer 200. In particular, the reaction enhancing layer 240 may be disposed at least one of between the P-layer 210 and the I-layer 220 or between the I-layer 220 and the N-layer 230. The reaction enhancing layer 240 may have a thickness of about 10 Å to about 200 Å. The reaction enhancing layer 240 may be varied in thickness and band gap according to a spectrum of indoor light incident into the I-layer 220. When the reaction enhancing layer 240 is manufactured by depositing thin-film silicon through a chemical vapor deposition (CVD) method, a band gap of the reaction enhancing layer 240 may be controlled by varying a mixture ratio between hydrogen and a silane (SiH₄) gas. The band gap of the reaction enhancing layer 240 may be typically adjusted from about 1.4 eV to about 2.0 eV, which is necessarily controlled according to a spectrum of indoor light. Through such an optimization, light absorbance may be enhanced to improve an efficiency of the solar cell. Also, the reaction enhancing layer 240 may have a refractive index different from that of the I-layer 220. For example, when the reaction enhancing layer 240 is disposed between the I-layer 220 and the P-layer 210, the reaction enhancing layer 240 may have a refractive index having a median value of refractive indexes of the I-layer 220 and the P-layer 210. For example, when the reaction enhancing layer 240 is disposed between the I-layer 220 and the N-layer 230, the reaction enhancing layer 240 may have a refractive index having a median value of refractive indexes of the I-layer 220 and the N-layer 230. For example, as the reaction enhancing layer 240 is disposed on one surface of the I-layer 220, a refractive index on light traveling path may not be remarkably varied. The reaction enhancing layer 240 may not be provided as necessary.

A first transparent electrode 300 may be disposed between the first substrate and the light absorbing layer 200. The first transparent electrode 300 may include a first light transmittance control layer 340 and a first selective wavelength control layer 330, which are sequentially stacked from the light absorbing layer 200 toward the first substrate 110. Hereinafter, a configuration of the first transparent electrode 300 will be described in detail.

The first selective wavelength control layer 330 may be disposed on the first substrate 110. The first selective wavelength control layer 330 may have a thickness of about 300 Å to about 2000 Å. The first selective wavelength control layer 330 may contain a silicon oxide (SiO₂), an aluminum oxide (Al₂O₃), an aluminum titanium oxide (AlTiO), a titanium oxide (TiO₂), a zinc oxide (ZnO), or a tin oxide (SnO₂). The first selective wavelength control layer 330 may selectively reflect or transmit the first light L1 that is incident through the first substrate 110 according to a thickness H1 thereof.

The first light transmittance control layer 340 may be disposed on the first selective wavelength control layer 330. The first light transmittance control layer 340 may have a thickness of about 200 Å to about 2000 Å. The first light transmittance control layer 340 may contain a zinc oxide (ZnO), a doped zinc oxide (ZnO), a titanium oxide (TiO₂), an indium oxide (In₂O₃), or a tin oxide (SnO₂). The first light transmittance control layer 340 may have a light transmittance that is varied according to a thickness thereof. That is, the first light transmittance control layer 340 may adjust a transmittance of the first light L1 that is incident through the first substrate 110 according to a thickness H2 thereof. The first selective wavelength control layer 330 and the first light transmittance control layer 340 may have a structural arrangement, a thickness, or a refractive index, which is controlled according to an optical spectrum distribution of the first light L1.

The first transparent electrode 300 may further include first conductive layers 320 disposed between the first substrate 110 and the first selective wavelength control layer 330 and between the first selective wavelength control layer 330 and the first light transmittance control layer 340. Each of the first conductive layers 320 may have a thickness of about 40 Å to about 1500 Å. The first conductive layers 320 may contain silver (Ag), copper (Cu), molybdenum (Mo), or an alloy thereof. The first conductive layers 320 may reduce a series resistance of the first transparent electrode 300.

The first transparent electrode 300 may further include a first seed layer 310 disposed between the first substrate 110 and the first selective wavelength control layer 330. The first seed layer 310 may contact the first substrate 110. The first seed layer 310 may have a thickness of about 100 Å to about 500 Å. The first seed layer 310 may contain a zinc oxide (ZnO), a doped zinc oxide (ZnO), a titanium oxide (TiO2), an indium oxide (In2O3), or a tin oxide (SnO2). The first seed layer 310 may be a seed for growing components of the first transparent electrode 300 on the first substrate 100 in a process of manufacturing the bi-facial transparent solar cell.

A second transparent electrode 400 may be disposed between the light absorbing layer 200 and the second substrate 120. The second transparent electrode 400 may include a second light transmittance control layer 440 and a second selective wavelength control layer 430, which are sequentially stacked from the light absorbing layer 200 toward the second substrate 120. Hereinafter, a configuration of the second transparent electrode 400 will be described in detail.

The second light transmittance control layer 440 may be disposed on the light absorbing layer 200. The second light transmittance control layer 440 may have a thickness of about 200 A to about 2000 A. The second light transmittance control layer 440 may contain a zinc oxide (ZnO), a doped zinc oxide (ZnO), a titanium oxide (TiO₂), an indium oxide (In₂O₃), or a tin oxide (SnO₂). The second light transmittance control layer 440 may have a light transmittance that is varied according to a thickness thereof. That is, the second light transmittance control layer 440 may adjust a transmittance of the second light L2 that is incident through the second substrate 120 according to a thickness H4 thereof.

The second selective wavelength control layer 430 may be disposed on the second light transmittance control layer 440. The second selective wavelength control layer 430 may have a thickness of about 300 Å to about 2000 Å. The second selective wavelength control layer 430 may contain a silicon oxide (SiO₂), an aluminum oxide (Al₂0₃), an aluminum titanium oxide (AlTiO), a titanium oxide (TiO₂), a zinc oxide (ZnO), or a tin oxide (SnO₂). The second selective wavelength control layer 430 may selectively reflect or transmit the second light L2 that is incident through the second substrate 120 according to a thickness H3 thereof. The second selective wavelength control layer 430 and the second light transmittance control layer 440 may have a structural arrangement, a thickness, or a refractive index, which is controlled according to an optical spectrum distribution of the second light L2.

The second transparent electrode 400 may further include second conductive layers 420 disposed between the light absorbing layer 200 and the second light transmittance control layer 440 and between the second light transmittance control layer 440 and the second selective wavelength control layer 430. Each of the second conductive layers 420 may have a thickness of about 40 Å to about 1500 Å. The second conductive layers 420 may contain silver (Ag), copper (Cu), molybdenum (Mo), or an alloy thereof. The second conductive layers 420 may reduce a resistance of the second transparent electrode 400.

The second transparent electrode 400 may further include a second seed layer 410 disposed between the light absorbing layer 200 and the second light transmittance control layer 440. The second seed layer 410 may have a thickness of about 100 Å to about 500 Å. The second seed layer 410 may contain a zinc oxide (ZnO), a doped zinc oxide (ZnO), a titanium oxide (TiO₂), an indium oxide (In₂O₃), or a tin oxide (SnO₂). The second seed layer 410 may be a seed for growing components of the second transparent electrode 400 on the light absorbing layer 200 in a process of manufacturing the bi-facial transparent solar cell.

The first transparent electrode 300 and the second transparent electrode 400 may be constituted such that the first and second light transmittance control layers 340 and 440 are disposed adjacent to the light absorbing layer 200, and the first and second selective wavelength control layers 330 and 430 are disposed adjacent to the first and second substrates 110 and 120, respectively. That is, the first and second light L1 and L2 incident from the outside may firstly pass through the first and second selective wavelength control layers 330 and 430 and then pass through the first and second light transmittance control layers 340 and 440.

The first light L1 incident into the first substrate 110 may be transmitted through the first transparent electrode 300 and then absorbed to the light absorbing layer 200. The second light L2 incident into the second substrate 120 may be transmitted through the second transparent electrode 400 and then absorbed to the light absorbing layer 200. As depletion is generated in the I-layer 220 included in the light absorbing layer 200 by the N-layer 230 and the P-layer 210, an electric-field is generated in the I-layer 220, and a pair of electron-hole is formed in the I-layer 220 by the first and second light L1 and L2. As the electron is collected to the N-layer 230, and the hole is collected to the P-layer 210 by the electric-field, a current flow.

The first transparent electrode 300 may allow incident light that is incident through the first substrate 110 to be selectively incident by the first selective wavelength control layer 330 and the light transmittance of the incident light to be adjusted by the first light transmittance control layer 340. For example, the thickness H1 of the first selective wavelength control layer 330 may be adjusted so that light that may be transmitted by the first selective wavelength control layer 330 has the same wavelength as that of the first light L1. The thickness H2 of the first light transmittance control layer 340 may be adjusted to improve a transmittance with respect to the incident first light L1. That is, the first transparent electrode 300 may be configured to effectively transmit the first light L1, and an amount of light incident into the light absorbing layer 200 may increase to enhance light power generation efficiency.

FIG. 3 is a schematic view for explaining a window to which the bi-facial transparent solar cell according to embodiments of the inventive concept is applied.

Referring to FIG. 3, the bi-facial transparent solar cell may be applied to a first window 10 between an indoor space and an outdoor space and a second window 20 between an indoor space and another indoor space. Sunlight L3 and first indoor light L4 may be incident into both surface of the first window 10, respectively. In the bi-facial transparent solar cell of the first window 10, each of the first transparent electrode and the second transparent electrode may be adjusted in structure, thickness, and configuration according to a spectrum of the indoor light in order to effectively transmit the sunlight L3 and the first indoor light L4. For example, the first window 10 may be configured such that each of the selective wavelength control layer and the light transmittance control layer, which are disposed at the outdoor side, is adjusted in thickness to effectively transmit the sunlight L3, and each of the selective wavelength control layer and the light transmittance control layer, which are disposed at the indoor side, is adjusted in thickness to effectively transmit the first indoor light L4. Accordingly, the first window 10 may perform light power generation by simultaneously absorbing the sunlight L3 and the first indoor light L4 during a daytime and may perform light power generation by absorbing the first indoor light L4 during a night time and a cloudy day. That is, the bi-facial solar cell according to embodiments of the inventive concept may be optimized to external conditions such as time, weather, and indoor-outdoor spaces and the optical spectrum of the indoor light, thereby performing the effective light power generation.

The first indoor light L4 and second indoor light L5 may be incident into both surface of the second window 20. In the bi-facial transparent solar cell of the second window 20, each of the first transparent electrode and the second transparent electrode may be adjusted in thickness and configuration in order to effectively transmit the first indoor light L4 and the second indoor light L5. For example, the second window 20 may be configured such that each of the selective wavelength control layer and the light transmittance control layer, which are disposed at the first indoor light L4 side, is adjusted in thickness to effectively transmit the first indoor light L4, and each of the selective wavelength control layer and the light transmittance control layer, which are disposed at the second indoor light L5 side, is adjusted in thickness to effectively transmit the second indoor light L5. That is, the bi-facial transparent solar cell according to embodiments of the inventive concept may be optimized to a spectrum condition of light of respective rooms to perform the effective light power generation. The above-described indoor light includes a daylight LED, a bulb color LED, which are currently selling in the market, and other modified LEDs having various spectra and fluorescent lamps. The spectrum of the indoor light may be analyzed before the bi-facial transparent solar cell according to an embodiment of the inventive concept is manufactured to design the optimized structure of the solar cell and the transparent electrode.

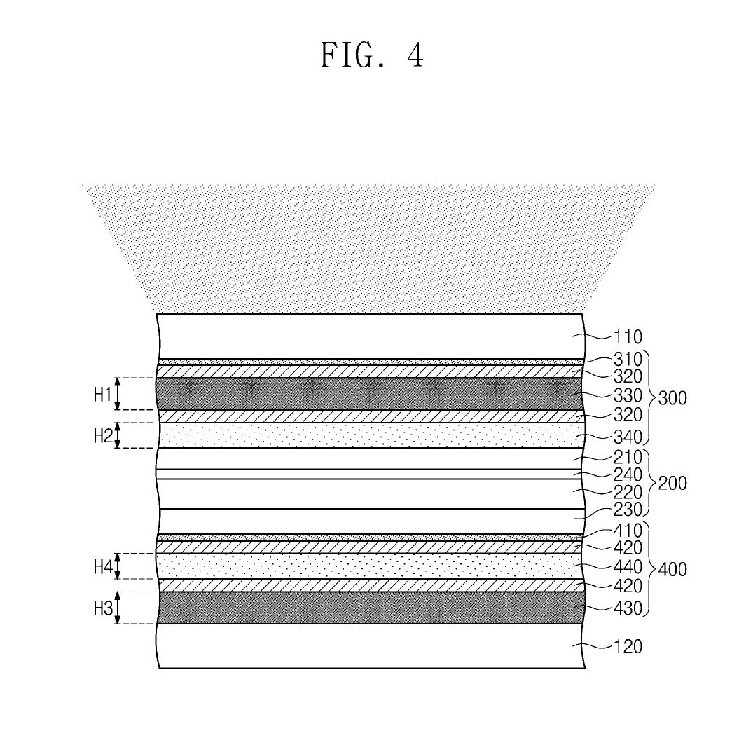

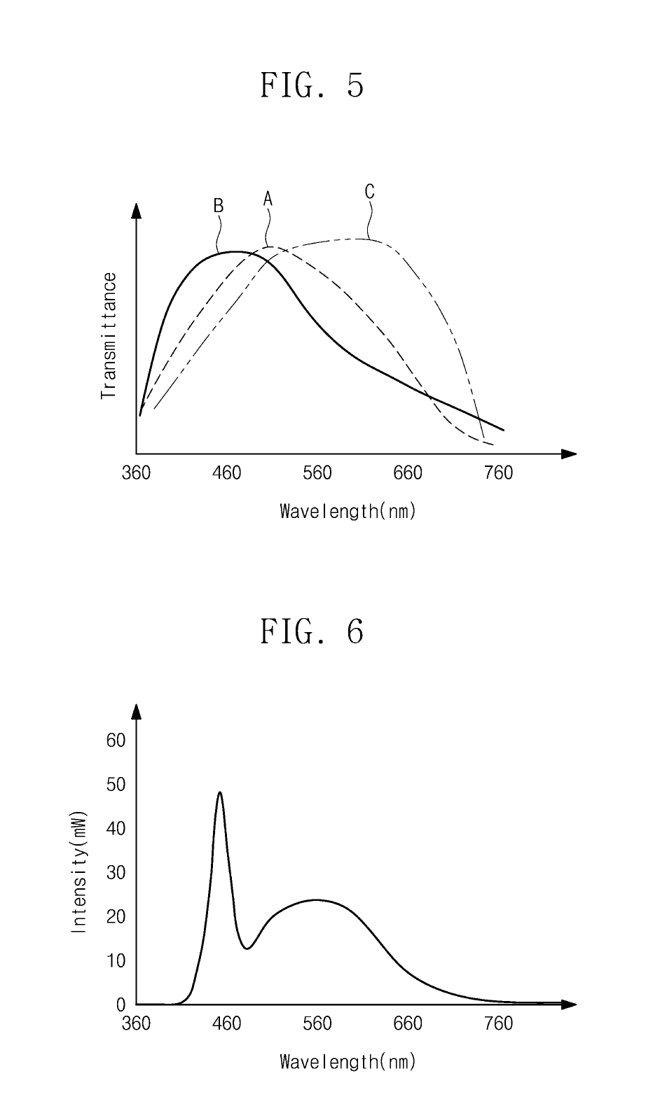

FIG. 4 is a cross-sectional view for explaining an operation of the first transparent electrode and illustrates light incident into the first transparent electrode. FIG. 5 is a view for explaining the transmittance of the first transparent electrode. FIG. 5 is a graph simulating a transmittance in which the first transparent electrode transmits incident light according to a wavelength on the basis of a thickness of the first selective wavelength control layer. In FIG. 5, (B) and (C) represent a bi-facial transparent solar cell in which the first selective wavelength control layer is varied in thickness. FIG. 6 is a graph exemplarily illustrating the wavelength of the light incident into the first transparent electrode.

Referring to FIG. 4, light is incident into the first transparent electrode 300. Here, the wavelength of light transmitted through the first transparent electrode 300 is simulated according to the thickness H1 of the first selective wavelength control layer 330. An embodiment A, which measures a light transmittance for each wavelength by allowing light to be incident into the first transparent electrode 300, is performed, and then light transmittances for each wavelength of an embodiment B, which increases the thickness H1 of the first selective wavelength control layer 330, and an embodiment C, which decreases the thickness H1 of the first selective wavelength control layer 330, are measured.

Referring to FIGS. 4 and 5, in the embodiment B, which increases the thickness H1 of the first selective wavelength control layer 330, the wavelength of the light transmitted through the first transparent electrode 300 decreases. In the embodiment C, which decreases the thickness H1 of the first selective wavelength control layer 330, the wavelength of the light transmitted through the first transparent electrode 300 increases. That is, according to an embodiment of the inventive concept, the thickness of the first selective wavelength control layer 330 may be adjusted so that the wavelength and transmittance of the light transmitted through the first transparent electrode 300 correspond to those of the incident first light L1. Thus, when the spectrum distribution of the indoor light is varied, the structure, thickness, and refractive index of the transparent electrode may be adjusted.

Like the first transparent electrode 300, the second transparent electrode 400 may allow the incident second light L2 that is incident through the second substrate 120 to be selectively incident by the second selective wavelength control layer 430 and the light transmittance of the incident light to be adjusted by the second light transmittance control layer 440. The thickness H3 of the second selective wavelength control layer 430 and the thickness H4 of the second light transmittance control layer 440 may be adjusted so that the wavelength and transmittance of the light transmitted through the second transparent electrode 400 correspond to those of the incident second light L2. That is, the second transparent electrode 400 may be configured to effectively transmit the second light L2, and an amount of light incident into the light absorbing layer 200 may increase to enhance light power generation efficiency.

When the spectrum distributions of the wavelengths of the first light L1 and the second light L2 are different, the thickness H1 of the first selective wavelength control layer 330 may be different from the thickness H3 of the second selective wavelength control layer 430. In this case, although the first light L1 and the second light L2, which have wavelengths different from each other, are incident into both sides of the bi-facial transparent solar cell, as the wavelengths of light transmitted through the first selective wavelength control layer 330 and the second selective wavelength control layer 430 are adjusted to be different, the light absorbance efficiency with respect to the first light L1 and the second light L2 may be enhanced.

Referring to FIGS. 1 and 2 again, the bi-facial transparent solar cell according to an embodiment of the inventive concept may be manufactured so that the first transparent electrode 300 and the second transparent electrode 400 optically convert the light having different wavelengths according to a usage environment. In particular, the first light L1 incident into the first substrate 110 and the second light L2 incident into the second substrate 120 may have wavelengths different from each other. For example, the first light L1 may be sunlight, and the second light L2 may be indoor illumination light.

The first light L1 may be incident into the first substrate 100 and sequentially transmitted through the first selective wavelength control layer 330 and the first light transmittance control layer 340, and the second light L2 may be incident into the second substrate 120 and sequentially transmitted through the second selective wavelength control layer 430 and the second light transmittance control layer 440. The thickness H1 of the first selective wavelength control layer 330 may be adjusted to transmit the first light L1, and the thickness H3 of the second selective wavelength control layer 430 may be adjusted to transmit the second light L2. Since the wavelength of the first light L1 is different from that of the second light L2, the thickness H1 of the first selective wavelength control layer 330 may be different from the thickness H3 of the second selective wavelength control layer 430. The incident light may have an optically converted wavelength that is different according to a firstly arrived layer. Accordingly, the wavelength of the light transmitted through the first transparent electrode 300 may be different from that of the light transmitted through the second transparent electrode 400.

Referring to FIG. 6, as an example of a condition in which the bi-facial transparent solar cell is used, indoor light having the spectrum distribution of FIG. 6 is incident into the first transparent electrode 300. As illustrated in FIG. 5, the indoor light incident into the first transparent electrode 300 has a highest intensity at a wavelength of about 450 nm to about 600 nm. Thus, the indoor light may have an intensity that is strong only as a specific wavelength.

When the indoor light is used for light power generation, the light power generation efficiency may be gradually enhanced as absorbance at a wavelength having the highest intensity increases. For this, the light transmittances of the transparent electrodes 300 and 400 at the corresponding wavelength are necessarily high. The bi-facial transparent solar cell according to an embodiment of the inventive concept may include the transparent electrodes 300 and 400 each having the light transmittance that is adjustable on the basis of the wavelength. For example, as illustrated in FIG. 6, indoor light having the highest intensity at a wavelength of about 450 nm to about 600 nm may be incident into the first transparent electrode 300. Here, in the embodiment of FIG. 5, the first transparent electrode 300 may have a configuration of that of the embodiments A and B, which each have a highest absorbance at a wavelength of about 450 nm to about 600 nm. Accordingly, the first transparent electrode 300 may have a high light transmittance with respect to the indoor light, and the light power generation efficiency of the bi-facial transparent solar cell may be high.

The bi-facial transparent solar cell according to embodiments of the inventive concept may be optimized to effectively absorb light incident into both sides of the bi-facial transparent solar cell by adjusting the configuration of the first transparent electrode 300 and the second transparent electrode 400. Accordingly, the bi-facial transparent solar cell may perform the effective light power generation according to the indoor and outdoor spaces and all sorts of illumination conditions. In addition, electrical conductivities of the transparent electrodes 300 and 400 may be determined by the conductive layers 320 and 420, and variation amounts of the thicknesses of the selective wavelength control layers 330 and 430 and the light transmittance control layers 340 and 440 may be small. That is, each of the transparent electrodes 300 and 400 may maintain a high electrical conductivity and, at the same time, effectively transmit the incident light.

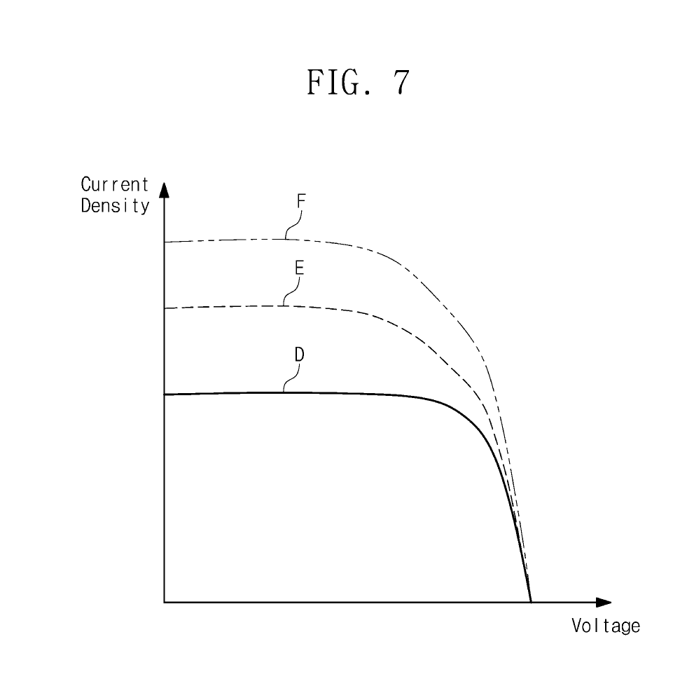

FIG. 7 is a graph for explaining a power production efficiency of the bi-facial transparent solar cell according to embodiments of the inventive concept. The graph is obtained by measuring current-voltage characteristics when light having different wavelengths is incident into the both surfaces of the bi-facial transparent solar cell. In FIG. 7, a reference symbol D represents a mono-facial solar cell that absorbs light through only one surface, a reference symbol E represents a bi-facial solar cell in which the transparent electrodes on both surfaces of the light absorbing layer transmit light having the same wavelength, and a reference symbol F represents the bi-facial solar cell according to an embodiment of the inventive concept. As illustrated in FIG. 7, the bi-facial solar cell according to an embodiment of the inventive concept may produce a photocurrent is greater than that of the mono-facial solar cell, which absorbs light through only one surface, and the bi-facial transparent solar cell, which absorbs only light having the same wavelength through both surfaces. That is, the bi-facial solar cell according to an embodiment of the inventive concept may increase the amount of absorbed light according to the light condition and the spectrum condition of the indoor light that is illuminated from the outside, thereby enhancing the light power generation efficiency.

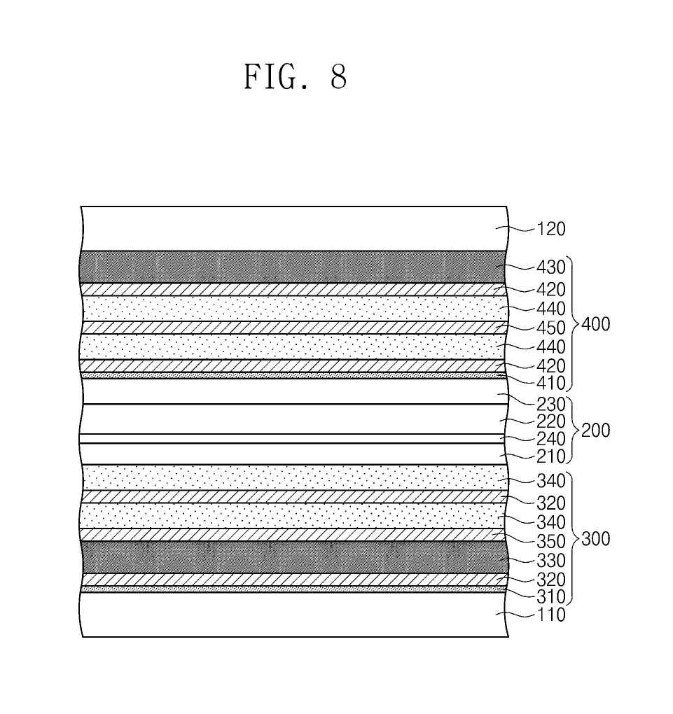

FIG. 8 is a cross-sectional view for explaining a bi-facial transparent solar cell according to embodiments of the inventive concept.

Referring to FIG. 8, the first light transmittance control layer 340 or the second light transmittance control layer 440 may be provided in plurality. Hereinafter, although embodiments, in which each of the first light transmittance control layer 340 and the second light transmittance control layer 440 are provided in plurality, are described as references, only one of the first light transmittance control layer 340 and the second light transmittance control layer 440 may be provided in plurality.

At least two first light transmittance control layers 340 may be sequentially stacked between the first selective wavelength control layer 330 and the light absorbing layer 200. Here, the first light transmittance control layers 340 may have thicknesses different from each other. That is, the first light transmittance control layers 340 may adjust a transmittance of the first light L1 that is incident through the first substrate 110 according to thicknesses thereof Alternatively, the first light transmittance control layers 340 may have the same thickness as each other.

A third conductive layer 350 may be disposed between the first light transmittance control layers 340. The third conductive layer 350 may have a thickness of about 40 A to about 1500 A. The third conductive layer 350 may contain silver (Ag), copper (Cu), aluminum (Al), or an alloy thereof.

At least two second light transmittance control layers 440 may be sequentially stacked between the second selective wavelength control layer 430 and the light absorbing layer 200. Here, the second light transmittance control layers 440 may have thicknesses different from each other. The second light transmittance control layers 440 may adjust a transmittance of the second light L2 that is incident through the second substrate 120 according to thicknesses thereof. Alternatively, the second light transmittance control layers 440 may have the same thickness as each other.

A fourth conductive layer 450 may be disposed between the second light transmittance control layers 440. The fourth conductive layer 450 may have a thickness of about 40 Å to about 1500 Å. The fourth conductive layer 450 may contain silver (Ag), copper (Cu), aluminum (Al), or an alloy thereof.

As the first light transmittance control layer 340 or the second light transmittance control layer 440 is provided in plurality, the light transmittance of the first transparent electrode 300 and the second transparent electrode 400 may be enhanced, and the third conductive layer 350 and the fourth conductive layer 450 may reduce series resistances of the first transparent electrode 300 and the second transparent electrode 400, respectively.

The bi-facial transparent solar cell according to the embodiments of the inventive concept may control the structure and thickness of the transparent electrodes disposed on the both sides thereof according to the spectrum of the indoor light and thus may effectively absorb or transmit the sunlight or the indoor light, which is illuminated to the both sides thereof Also, as the amount of light incident into the light absorbing layer increases, all of the light power generation efficiency and the transparency may improve.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed. Therefore, the above-disclosed embodiments are to be considered illustrative and not restrictive.

What is claimed is:

1. A bi-facial transparent solar cell comprising:
a first substrate and a second substrate disposed on the first substrate;
a light absorbing layer disposed between the first substrate and the second substrate;
a first transparent electrode disposed between the first substrate and the light absorbing layer; and
a second transparent electrode disposed between the second substrate and the light absorbing layer,
wherein the first transparent electrode and the second transparent electrode each transmit lights having wavelengths different from each other.

2. The bi-facial transparent solar cell of claim 1, wherein the first transparent electrode comprises a first light transmittance control layer and a first selective wavelength control layer, which are sequentially stacked toward the first substrate from the light absorbing layer, and
the second transparent electrode comprises a second light transmittance control layer and a second selective wavelength control layer, which are sequentially stacked toward the second substrate from the light absorbing layer.

3. The bi-facial transparent solar cell of claim 2, further comprising a conductive layer disposed on at least one of both surfaces of the first light transmittance control layer and at least one of both surfaces of the second light transmittance control layer.

4. The bi-facial transparent solar cell of claim 2, further comprising: a first seed layer disposed between the first substrate and the first selective wavelength control layer; and
a second seed layer disposed between the second light transmittance control layer and the light absorbing layer.

5. The bi-facial transparent solar cell of claim 2, wherein the first light transmittance control layer or the second light transmittance control layer is provided in plurality.

6. The bi-facial transparent solar cell of claim 2, wherein the first light transmittance control layer and the second light transmittance control layer have thicknesses different from each other, and
the first selective wavelength control layer and the second selective wavelength control layer have thicknesses different from each other.

7. The bi-facial transparent solar cell of claim 1, wherein the light absorbing layer comprises a P-layer, a I-layer, and a N-layer, which are sequentially stacked.

8. The bi-facial transparent solar cell of claim 7, further comprising a reaction enhancing layer disposed at least one of between the P-layer and the I-layer and between the I-layer and the N-layer.

9. The bi-facial transparent solar cell of claim 1, wherein the light absorbing layer contains amorphous silicon, microcrystalline silicon, silicon-germanium, a silicon oxide, a silicon nitride, or a silicon carbide.

10. The bi-facial transparent solar cell of claim 1, wherein light incident into the first transparent electrode is sunlight, and
light incident into the second transparent electrode is indoor light.

11. The bi-facial transparent solar cell of claim 10, wherein the indoor light is light emitted from a bulb color LED, a daylight LED, or a fluorescent lamp.
